(19) United States
(12) Patent Application Publication
(10) Pub. No.: US 2010/0117105 A1
(43) Pub. Date: May 13, 2010

(54) LIGHT-EMITTING DEVICE AND METHOD FOR FABRICATING THE SAME

(75) Inventors: Do Yeol Ahn, Seoul (KR); Seoung Hwan Park, Daegu (KR)

Correspondence Address: HUSCH BLACKWELL SANDERS LLP, 190 Carondelet Plaza, Suite 600, ST. LOUIS, MO, 63105, US

(73) Assignee: WOOREE LST CO. LTD., Gyeonggi-do (KR)

(21) Appl. No.: 12/667,141

(22) PCT Filed: Jun. 17, 2008
(86) PCT No.: PCT/KR08/03419

§ 371 Date: Dec. 29, 2009

(30) Foreign Application Priority Data
Jun. 29, 2007 (KR) 10-2007-0065301

(51) Int. Cl. H01L 33/00; H01L 31/00

(52) U.S. Cl. 257/94; 438/47; 257/E33.001; 257/E31.001

(57) ABSTRACT

Disclosed are a light-emitting diode and a method for fabricating the same. The ternary or quaternary Group III-V nitride semiconductor light-emitting diode comprises a buffer layer doped with conductive impurities and developed with an orientation inclined toward the axis [1122] at an angle of 40° to 70° with respect to the axis [0001] on a [0001]-oriented substrate, a light-emitting layer arranged on the buffer layer, a first electrode arranged under the buffer layer, and a second electrode arranged on the light-emitting layer, wherein the light-emitting layer includes a first clad layer arranged on the buffer layer, an activation layer arranged on the first clad layer and a second clad layer arranged on the activation layer. According to the semiconductor light-emitting diode, the light-emitting layer is formed on the substrate with an orientation inclined toward the axis [1122] at an angle of 40° to 70° with respect to the axis [0001], and compositions of Group III-V and Group II-VI compounds constituting the first and second clad layers are controlled. As a result, it is possible to offset the stresses applied to the activation layer and prevent spontaneous polarization. As a result, the light-emitting diode can exhibit improved light efficiency.

### TECHNICAL FIELD

The present invention relates to a light-emitting device. More particularly, the present invention relates to a light-emitting device with improved light-emission efficiency and a method for fabricating the light-emitting device.

### BACKGROUND ART

Light-emitting diodes (LEDs) were first researched in the early 1960s and have been commercially available since the late 1960s. Since the 1960s, LEDs have received a great deal of attention, based on their superior characteristics such as vibration resistance, high reliability and low power consumption. However, initially-developed LEDs had a limited range of applications, such as display lamps in spaceships and aircraft, due to their high price.

Since LEDs introduced in the 1960s render only monochromatic light, they can improve energy efficiency without unnecessary waste. To date, LEDs have limited range of applications, such as specific displays.

With the progress of high-quality AlGaInP (red, orange, amber) and GaInN (blue, green) LEDs developed by Metal Organic Chemical Vapor Deposition (MOCVD), LEDs are widely utilized in a variety of applications including internal illuminators and brakes of automobiles, traffic signals, full-natural colors of displays, outdoor electric signs, cellular phone/PDA backlight illuminators and other decorative LEDs.

LEDs include a light-emitting device which converts applied electric energy into light, to emit light.

All substances consist of atoms, each of which has a nucleus. The electron revolves in a circular orbit around the nucleus. The further the distance between the orbit and the nucleus, the higher the energy the electron revolving in the orbit has.

When an electron revolving in a lower orbit gains energy from an external source, it jumps from the allowed orbit to a higher orbit. An unstable electron revolving in a higher orbit falls into a lower orbit by releasing energy. LEDs convert the released energy into light.

LEDs differ in levels to which electrons jump or fall according to materials thereof and thus generate different levels of energy. Specifically, when the light is generated in a low energy level, it has a long wavelength and renders red, and on the other hand, when the light is generated in a high energy level, it has a short wavelength and renders blue.

Based on such a principle, three colors (i.e. red, green and blue) of LEDs are combined to realize full-color.

Of these, red LEDs were the first to become commercially available. In particular, GaAsP-based red LEDs were first introduced by General Electric Corp., in 1962.

Initially-developed LEDs were fabricated on a small scale and thus exhibited low performance. However, since LEDs were mass-produced by Monsanto and Hewlett-Packard in the late 1960s, they have been intensely researched and practically used in the U.S.

When heterojunction red LEDs in which GaAlAs is developed on a GaAs substrate were developed, a great deal of intense research was devoted to red LEDs in Japan during the 1980s and high-brightness red LEDs have been commercially available since then. In particular, green LEDs employing AlGaAs as a material came into the spotlight, because they exhibited higher energy conversion efficiency than incandescent lamps (i.e., 1%).

A great deal of research continues to be devoted to the development of novel semiconductor materials. Recent technical progress in the development of quaternary compounds (e.g. indium gallium aluminum phosphide (nitride) (InGaAlP(InGaAlN)) semiconductor thin films) ensures LEDs with high brightness and high luminescence, as compared to incandescent lamps.

The term “compound semiconductor” as used herein refers to a semiconductor composed of a compound of two or more elements. Examples of compound semiconductors include: Group III-V compound semiconductors such as gallium arsenide (GaAs), indium phosphide (InP), gallium phosphide (GaP) compound semiconductors; Group II-VI compound semiconductors such as cadmium sulfide (CdS) and zinc telluride (ZnTe) compound semiconductors; and Group IV-VI compound semiconductors such as lead sulfide (PbS) compound semiconductors.

Compound semiconductors are different from single-element semiconductors, e.g., germanium (Ge) or silicon (Si) semiconductors, in terms of carrier mobility and band structure. This carrier mobility and band structure difference leads to large differences in electrical and optical properties between the two types of semiconductors. Compound semiconductors with desired properties, selected from various compound semiconductors, are used to fabricate LEDs which cannot be realized with the single-element (e.g. silicon (Si) and germanium (Ge)) semiconductors.

FIG. 1 is a sectional view illustrating a general Group III-V nitride semiconductor light-emitting diode.

Referring to FIG. 1, a general Group III-V nitride semiconductor light-emitting diode 1 comprises a buffer layer 50 doped with conductive impurities, a light-emitting layer 10 arranged on the buffer layer 50, a first electrode 60 arranged under the buffer layer 50 and a second electrode 70 arranged on the light-emitting layer 10.

The light-emitting layer 10 comprises a first clad layer 20 generating carriers for light-emission from an electric field applied through the buffer layer 50, a second clad layer 40 generating carriers for light-emission from an electric field applied from the second electrode 70, and an activation layer 30 interposed between the first clad layer 20 and the second clad layer 40 and emitting light.

The first clad layer 20 and the second clad layer 40 constituting the light-emitting layer 10 are semiconductor layers composed of a compound of Group III-V elements e.g. In, Ga, Al, P or AS.

The structure of the light-emitting diode 1 enables conversion of electric energy derived from an electric field applied to both the electrodes 60 and 70 into light energy, to emit light.

Group III-V compound semiconductors constituting LEDs that emit celadon green and bluish green light have structural drawbacks in that stress inevitably applied to the light-emitting layer 10, causes formation of piezoelectric fields in the first and second clad layers 20 and 40, as shown in FIG. 2, thus resulting in physical deformation of the light-emitting layer 10. Disadvantageously, due to spontaneous polarization, group III-V compound semiconductors have considerably lower luminescence than other compound semiconductors. A theoretical model for such a phenomenon was grounded on Park et al., Appl. Phys. Lett. 75. 1354 (1999).

Group II-VI oxide semiconductors currently in the spotlight also suffer from occurrence of stress due to piezoelectric phenomenon and spontaneous polarization. The theoretical model for such a phenomenon is based on S.-H. Park and D. Ahn, Appl. Phys. Lett. 87, 253509 (2005), D. Ahn et al., Photonics Technol Lett. 18, 349 (2006).

In particular, several methods for removing spontaneous polarization have been reported to date. For example, nonpolar substrates, which vary a specific direction in which crystals are developed on a substrate, may be used. Another method is to form clad layers with quaternary compound films in which an aluminum (Al) composition in the quaternary compound is increased, to improve carrier confinement effects and increase luminescent efficiency.

The theoretical ground for the use of the non- or semi-polar substrates was disclosed in Park & Chuang, Phys. Rev. B59, 4725 (1999), Waltereit et al., Nature 406, 865 (2000).

However, non-polar substrates have difficulty realizing high quality due to incomplete techniques for development of crystals in the crystal development direction.

In order to obtain non-polar substrates with high-quality, several epitaxy processes must be carried out. This requirement entails a complicated fabrication process, deteriorated fabrication efficiency and increased fabrication cost. These drawbacks of non-polar substrates are disclosed in K. Nishizuka et al., appl. phys. Lett. 87, 231901 (2005).

The first and second clad layers 20 and 40 are composed of aluminum (Al)-containing quaternary compound semiconductors and a composition of the aluminum (Al) in the compound is increased, thereby improving carrier confinement effects and luminescent efficiency. Such a principle is disclosed in Zhang et al., Appl. Phys. Lett. 77, 2668 (2000); and Lai et al., IEEE Photonics Technol. Lett. 13, 559 (2001).

However, these methods cannot fundamentally eliminate the phenomena of piezoelectric fields and spontaneous polarization and the problem of deteriorated luminescence properties of LEDs thus remains unsolved. Accordingly, there is a need for LEDs with improved optical properties by which stress and spontaneous polarization is controlled, and a method for fabricating the same.

### DISCLOSURE

### Technical Problem

An object of the present invention devised to solve the problem lies on a compound semiconductor light-emitting device with improved light-emission efficiency by which piezoelectric fields and spontaneous polarization are removed from a light-emitting layer, and a method for fabricating the light-emitting device.

### Technical Solution

The object of the present invention can be achieved by providing a ternary or quaternary Group III-V nitride semiconductor light-emitting diode comprising: a buffer layer doped with conductive impurities and developed with an orientation inclined toward the axis [11 2̅2] at an angle of 40° to 70° with respect to the axis [0001] on a [0001]-oriented substrate; a light-emitting layer arranged on the buffer layer; a first electrode arranged under the buffer layer; and a second electrode arranged on the light-emitting layer, wherein the light-emitting layer includes a first clad layer arranged on the buffer layer, an activation layer arranged on the first clad layer and a second clad layer arranged on the activation layer.

In another aspect of the present invention, provided herein is a ternary Group III-V nitride semiconductor light-emitting diode comprising: a buffer layer doped with conductive impurities and developed with an orientation inclined toward the axis [11 2̅2] at an angle of 40° to 70° with respect to the axis [0001] on a [0001]-oriented substrate; a light-emitting layer arranged on the buffer layer; a first electrode arranged under the buffer layer; and a second electrode arranged on the light-emitting layer, wherein the light-emitting layer includes a first clad layer arranged on the buffer layer, an activation layer arranged on the first clad layer and a second clad layer arranged on the activation layer, wherein the first clad layer includes a first material with a first composition, and the second clad layer includes a second material having the same element as the first material and a second composition different from the first composition.

In another aspect of the present invention, provided herein is a quaternary Group III-V nitride semiconductor light-emitting diode comprising: a buffer layer doped with conductive impurities and developed with an orientation inclined toward the axis [11 2̅2] at an angle of 40° to 70° with respect to the axis [0001] on a [0001]-oriented substrate; a light-emitting layer arranged on the buffer layer; a first electrode arranged under the buffer layer; and a second electrode arranged on the light-emitting layer, wherein the light-emitting layer includes a first clad layer arranged on the buffer layer, an activation layer arranged on the first clad layer and a second clad layer arranged on the activation layer, wherein the first clad layer includes a first material with a first composition and a second material with a second composition, and the second clad layer includes a second material having the same element as the first material and a second composition different from the first composition.

In another aspect of the present invention, provided herein is a ternary or quaternary Group II-VI oxide semiconductor light-emitting diode comprising: a buffer layer doped with conductive impurities and developed with an orientation inclined toward the axis [11 2̅2] at an angle of 40° to 70° with respect to the axis [0001] on a [0001]-oriented substrate; a light-emitting layer arranged on the buffer layer; a first electrode arranged under the buffer layer; and a second electrode arranged on the light-emitting layer, wherein the light-emitting layer includes a first clad layer arranged on the buffer layer, an activation layer arranged on the first clad layer and a second clad layer arranged on the activation layer.

In another aspect of the present invention, provided herein is a ternary Group II-VI oxide semiconductor light-emitting diode comprising: a buffer layer doped with conductive impurities and developed with an orientation inclined toward the axis [11 2̅2] at an angle of 40° to 70° with respect to the axis [0001] on a [0001]-oriented substrate; a light-emitting layer arranged on the buffer layer; a first electrode arranged under the buffer layer; and a second electrode arranged on the light-emitting layer,

wherein the light-emitting layer includes a first clad layer arranged on the buffer layer, an activation layer arranged on the first clad layer and a second clad layer arranged on the activation layer, wherein the first clad layer includes a first material with a first composition, and the second clad layer includes a second material having the same element as the first material and a second composition different from the first composition.

In another aspect of the present invention, provided herein is a quaternary Group II-VI oxide semiconductor light-emitting diode comprising: a buffer layer doped with conductive impurities and developed with an orientation inclined toward the axis [11 2̅2] at an angle of 40° to 70° with respect to the axis [0001] on a [0001]-oriented substrate; a light-emitting layer arranged on the buffer layer; a first electrode arranged under the buffer layer; and a second electrode arranged on the light-emitting layer, wherein the light-emitting layer includes a first clad layer arranged on the buffer layer, an activation layer arranged on the first clad layer and a second clad layer arranged on the activation layer, wherein the first clad layer includes a first material having a first composition and a second material having a second composition, and the second clad layer includes a third material having the same element as the first material and a third composition different from the first composition, and a fourth material having the same element as the second material and a fourth composition different from the second composition.

In another aspect of the present invention, provided herein is a ternary or quaternary Group II-VI oxide semiconductor light-emitting diode comprising: a buffer layer doped with conductive impurities and developed with an orientation inclined toward the axis [11 2̅2] at an angle of 15° with respect to the axis [0001] on a [0001]-oriented substrate; a light-emitting layer arranged on the buffer layer; a first electrode arranged under the buffer layer; and a second electrode arranged on the light-emitting layer,

wherein the light-emitting layer includes a first clad layer arranged on the buffer layer, an activation layer arranged on the first clad layer and a second clad layer arranged on the activation layer.

In another aspect of the present invention, provided herein is a method for fabricating a ternary or quaternary compound semiconductor light-emitting diode comprising: forming a sacrificial layer on a substrate such that the sacrificial layer has an orientation inclined toward the axis [11 2̅2] at an angle of 40° to 70° with respect to the axis [0001] on a [0001]-oriented substrate; forming a conductive impurity-doped buffer layer on the sacrificial layer; forming a light-emitting layer on the buffer layer; removing the sacrificial layer; and forming a first electrode under the buffer layer and forming a second electrode on the second clad layer.

### DESCRIPTION OF DRAWINGS

The accompanying drawings, which are included to provide a further understanding of the invention, illustrate embodiments of the invention and together with the description serve to explain the principle of the invention.

In the drawings:

FIG. 1 is a sectional view illustrating a general Group III-V nitride semiconductor light-emitting diode;

FIG. 2 is a sectional view showing deformation of a light-emitting layer resulting from piezoelectric fields;

FIG. 3 is a sectional view illustrating the structure of a quaternary nitride semiconductor light-emitting diode according to a first embodiment of the present invention;

FIG. 4 is a sectional view illustrating the structure of a quaternary compound semiconductor light-emitting diode in which a clad layer includes a p-type delta-doped layer;

FIG. 5 is a sectional view illustrating a state in which stress is applied to the activation layer and clad layers in a semiconductor including n layers;

FIG. 6 is a sectional view illustrating the structure of a ternary nitride compound semiconductor light-emitting diode according to a second embodiment of the present invention;

FIG. 7 is a graph showing piezoelectric fields and spontaneous polarization generated on the activation layer and clad layers of the semiconductor light-emitting diodes according to the first and second embodiments of the present invention;

FIG. 8 is a graph showing internal fields applied to the light-emitting layers as a function of crystal angle (θ) with respect to semiconductor LEDs according to the first and second embodiments of the present invention;

FIGS. 9 and 10 are graphs comparing optical properties of a LED employing a [10 1̅0]-oriented nonpolar substrate and the quaternary nitride semiconductor LEDs tilted 56° toward the axis [11 2̅2] according to the first and second embodiments of the present invention;

FIG. 11 is a sectional view illustrating the structure of a semiconductor light-emitting diode according to a third embodiment of the present invention.

FIG. 12 is a graph showing piezoelectric field applied to the light-emitting layer of the semiconductor light-emitting diode according to the third embodiment of the present invention;

FIG. 13 is a graph showing internal field applied to the light-emitting layer as a function of crystal angle (θ) with respect to the semiconductor LED according to the third embodiment of the present invention;

FIGS. 14 and 17 are graphs showing distribution of holes confined in an activation layer as a function of crystal angle (θ);

FIG. 18 is a graph showing optical gain as a function of crystal angle (θ), with respect to the semiconductor LED according to the third embodiment of the present invention;

FIGS. 19 and 20 are graphs showing optical properties as a function of crystal angle (θ), with respect to the LED according to the third embodiment of the present invention;

FIG. 21 is a sectional view illustrating the structure of a semiconductor light-emitting diode according to a fourth embodiment of the present invention;

FIGS. 22 and 28 are sectional views illustrating a method for fabricating the semiconductor light-emitting diodes according to the embodiments of the present invention; and

FIGS. 29 and 30 are sectional views illustrating a method for forming a p-type delta-doped layer in the clad layer shown in FIG. 4.

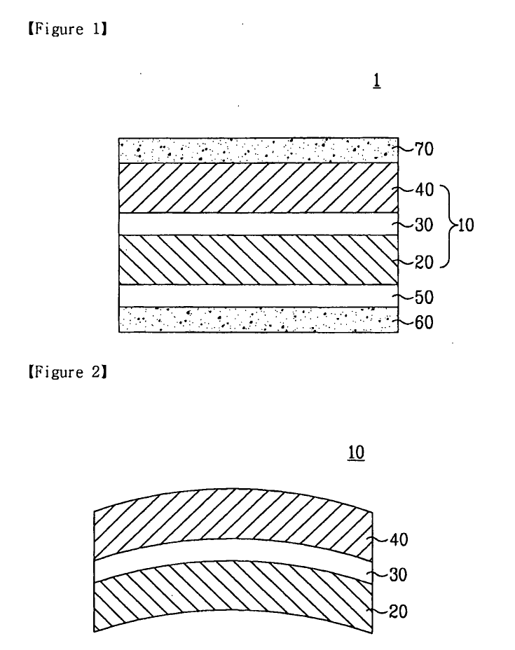

### BEST MODE

Reference will now be made in detail to the preferred embodiments of the present invention, examples of which are illustrated in the accompanying drawings.

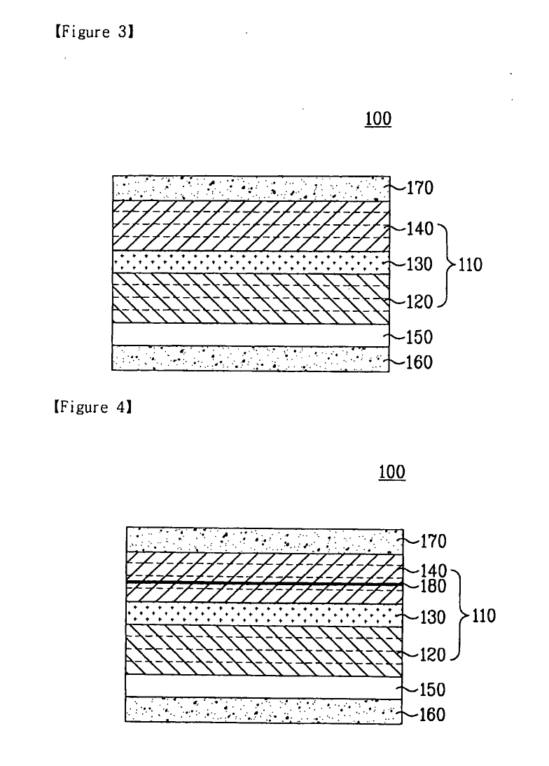

FIG. 3 is a sectional view illustrating the structure of a quaternary nitride compound semiconductor light-emitting diode according to a first embodiment of the present invention.

Referring to FIG. 3, a quaternary nitride semiconductor light-emitting diode 100 according to an embodiment of the present invention comprises a buffer layer 150 doped with conductive impurities and developed with an orientation inclined toward the axis [11 2̅2] at an angle of 40° to 70° with respect to the axis [0001] on a [0001]-oriented substrate, a light-emitting layer 110 arranged on the buffer layer 150, a first electrode 160 arranged under the buffer layer 150 and a second electrode 170 arranged on the light-emitting layer 100.

The light-emitting layer 110 includes a first clad layer 120 generating carriers for light-emission from an electric field applied through the buffer layer 150, a second clad layer 140 generating carriers for light-emission from an electric field applied from the second electrode 170, and an activation layer 130 interposed between the first clad layer 130 and the second clad layer 150 and emitting light.

The activation layer 130, the first clad layer 120 and the second clad layer 140 constituting the light-emitting layer 110 are nitride semiconductors composed of a compound of Group III-V elements such as nitrogen (N), indium (In), gallium (Ga), aluminum (Al), phosphorus (P) or arsenic (As).

The activation layer 130 is a single-crystal semiconductor having quantum wells composed of a compound of Group III-V elements e.g. GaN or InₓGa₁₋ₓN.

In the ternary compound, InₓGa₁₋ₓN, constituting the activation layer 130, an indium (In) composition X is in the range of 0<X<1.

The first clad layer 120 and the second clad layer 140 arranged over and under the activation layer 130, respectively, are single-crystal semiconductors composed of a quaternary compound (e.g. AlₓIn_{y}Ga_{1-x-y}N) of Group III-V elements.

Among elements constituting the quaternary compound film of the first and second clad layers 120 and 140, the aluminum (Al) composition X and the indium (In) composition Y are combined in a predetermined ratio, such that the first and second clad layers 120 and 140 have an energy band gap of about 4.0 eV.

Based on the structure of the light-emitting diode 100, the light-emitting layer 110 converts electric energy, which is derived from an electric field applied to the first electrode 160 and the second electrode 170 arranged in lower and upper parts of the light-emitting diode 100, respectively, to light energy, to emit light.

The first and the second clad layers 120 and 140 are semiconductor layers developed on a substrate having an orientation inclined toward the axis [11 2̅2] at an angle of 40 to 60 degrees (most preferably, 56 degrees) with respect to the axis [1001], instead of nonpolar substrates with the orientation [10 1̅0], suffering from several drawbacks due to incomplete heterocrystal development techniques.

Of elements in the quaternary compound AlₓIn_{y}Ga_{1-x-y}N constituting the first and second clad layers 120 and 140, an indium (In) composition X and an aluminum (Al) composition Y are adjusted in the range of 0<X≦0.3 and 0<Y≦0.3, respectively. As a result, a gallium composition is in the range of 0.4≦Ga<1.

The indium (In), aluminum (Al) and indium (In) compositions are adjusted to desired levels such that the first and second clad layers 120 and 140 have an energy band gap of about 4.0 eV.

Furthermore, by employing aluminum (Al) and indium (In) compositions, eliminating internal fields of the activation layer 130 resulting from piezoelectric fields and spontaneous polarization, while rendering the first and second clad layers 120 and 140 to have an energy band gap of about 4.0 eV, it is possible to improve light generation efficiency of the activation layer 130.

The aluminum (Al) and indium (In) compositions of the first clad layer 120 may be symmetrical to those of the second clad layer 140 within the respective predetermined ranges.

Specifically, when aluminum (Al) of the first clad layer 120 has a first composition in the range of 0<Y≦0.3, aluminum (Al) of the second clad layer 140 has a second composition Y′ in the range of 0<Y′≦0.3, different from the first composition Y. For example, when the first composition Y is 0.1, the second composition Y′ is 0.3.

By symmetrically controlling aluminum (Al) compositions Y and Y′ of first and second clad layers 120 and 140 within the desired ranges, it is possible to offset the activation layer 130 and prevent spontaneous polarization.

Similarly, by symmetrically controlling indium (In) compositions X and X′ of first and second clad layers 120 and 140 within the desired ranges, it is possible to offset stresses applied to the activation layer 130 and prevent spontaneous polarization.

As shown in FIG. 4, a P-type material e.g. magnesium (Mg) is doped into the second clad layer 140 to form a p-type delta-doped layer 180. The delta-doped layer 180 is close to the activation layer 130 inside the clad layer 140. The delta-doped layer 180 serves to compensate decreased polarization fields.

As mentioned above, the delta-doped layer 180 is formed inside the second clad layer 140. Alternatively, the delta-doped layer 180 may be formed inside the first clad layer 120, or inside both the first and second clad layers 120 and 140.

The delta-doped layer 180 may be applicable to ternary Group III-V nitride semiconductors as well as quaternary Group III-V nitride semiconductors, and furthermore, ternary and quaternary Group II-V oxide semiconductors.

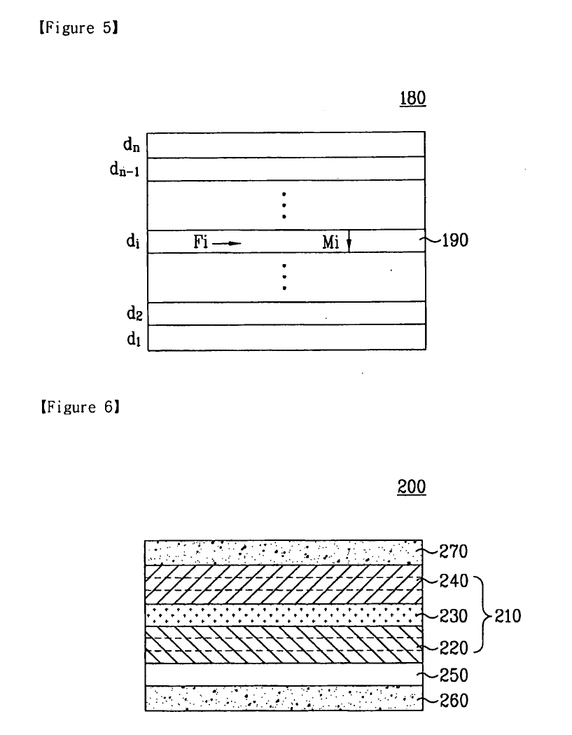

FIG. 5 is a sectional view illustrating a state in which stress is applied to the activation layer and clad layers in a semiconductor including n layers.

As shown in FIG. 5, in a semiconductor layer 180 having n layers, the stress F, applied to an i^{th} layer 190 is calculated according to the following Equation 1. The theoretical basis thereof is disclosed in K. Nakajima, J. Appl. Phys. 72. 5213 (1992).

$$Fi = \frac{{E}_{i} {d}_{i}}{{a}_{i} Q \frac{{E}_{j} {d}_{j}}{{a}_{j}}} s [ \begin{matrix}\frac{1}{R} {Q}_{j} ( \frac{{E}_{j} {d}_{j}}{{a}_{j}} ) \{ \begin{matrix}{Q}_{A < i} {a}_{k} {d}_{k} - {Q}_{A < j} {a}_{k} {d}_{k} + \\ \frac{{a}_{i} {d}_{i} - {a}_{j} {d}_{j}}{2}\end{matrix} \} + \\ {Q}_{j} ( \frac{{E}_{j} {d}_{j}}{{a}_{j}} ) ( {l}_{j} - {l}_{i} )\end{matrix} ] \qquad Equation 1$$

wherein dᵢ is a thickness of the i^{th} layer of n layers, aᵢ is a lattice constant of the i^{th} layer, Eᵢ is the Young's modulus, and Lᵢ is an effective lattice constant of the i^{th} layer, reflecting thermal expansion, as is given by the following Equations 2 to 5.

The term “Young's modulus” as used herein refers to an elastic modulus introduced by T. Young in 1807.

When both ends of a bar having a uniform thickness are drawn, a deformation force T exerted by the bar is proportional to tensile strain A of an amount by which the length of the bar changes (compression or stretching) per an original length, within an elastic limit. The ratio E=T/A refers to the Young's modulus, also known as “elastic modulus”. The Young's modulus of a physical body is a fixed value, independent of thickness and length.

$$\begin{matrix}i = {a}_{i} ( 1 + {α}_{i} T ) & Equation 2 \\ {l}_{i + 1} [ 1 + {e}_{i + 1} ( {F}_{i + 1} ) - {e}_{i + 1} ( {M}_{i + 1} ) ] = {l}_{i} [ 1 + {e}_{i} ( {F}_{i} ) + {e}_{i} ( {M}_{i} ) ] & Equation 3 \\ {e}_{i} ( {F}_{i} ) = \frac{{F}_{i}}{{E}_{i} {d}_{i}} & Equation 4 \\ {e}_{i} ( {M}_{i} ) = \frac{{d}_{i}}{2 R} & Equation 5\end{matrix}$$

In the Equations, eᵢ is an effective strain applied to the i^{th} layer among n layers, and R is a curvature of a substrate. The curvature of the sapphire substrate is in the range of 6 m to 12 m. It can be confirmed from the Equations above that in the case of N=3, the quaternary compound has a desired composition, enabling efficient elimination of the strain of the activation layer 130.

When the indium (In) composition is increased, a compressive stress is applied to the first clad layer 120 and the second clad layer 140.

The term “stress” as used herein, also known as “deformation force”, refers to an internal force acting within a body to maintain its shape, as a reaction to external applied forces.

Based on the direction in which a force acts to the major axis of a body, the stress is divided into shearing stress, tensile stress (also known as “tension”) and compressive stress. Even at the same site in a body, the type and intensity of stresses are varied depending upon the direction in which a force acts to the major axis of the body.

When both ends of a bar having a uniform cross-section are drawn with a force P, the bar is stretched by the force P. As the force is increased, the bar is finally broken (cut). In response to the force P, a number of actions/reactions (herein, referred to as internal forces) occur between a large number of fine particles within the body.

Although these internal forces are invisible, it may be assumed that the bar has an imaginary cross-section m-n cut perpendicular to its major axis. In this case, in a lower part of the cross-section m-n, an external force p acts from the bottom of the bar to the outside, and in an upper part of the cross-section m-n, internal forces act between high-level particles and low-level particles. The internal forces are uniformly distributed on the cross-section. A sum of the internal forces m-n corresponds to the external force p acting in the upper part.

Accordingly, a pair of internal forces with the same intensity and opposite direction act to a cross-section inside a body. Such an internal force is referred to as a “stress (deformation force)”.

The tensile stress and compressive stress depend upon the indium (In) composition. Specifically, a turning point between the tensile stress and compressive stress occurs at 6% indium (In). More specifically, when the indium (In) composition is less than 6%, tensile stress is applied, and on the other hand, when the indium (In) composition is more than 6%, a compressive stress is applied.

In a case where general gallium substrates are developed, when a tensile stress is applied, spontaneous polarization and piezoelectric fields are in parallel. On the other hand, when a compressive stress is applied, spontaneous polarization and piezoelectric fields are formed in opposite directions.

FIG. 6 is a sectional view illustrating the structure of a ternary nitride compound semiconductor light-emitting diode according to a second embodiment of the present invention.

As shown in FIG. 6, a ternary nitride compound semiconductor light-emitting diode 200 of the second embodiment has the same structure as that of the first embodiment, except for the structure of first and second clad layers 220 and 240. Thus, a more detailed description of other constituent components will be appreciated from the first embodiment.

As shown in FIG. 6, the ternary nitride compound semiconductor light-emitting diode 200 employs ternary nitrides as materials for the first and second clad layers 220 and 240 constituting a light-emitting layer 210. Based on the structure, the ternary nitride compound semiconductor light-emitting diode 200 enables control of spontaneous polarization and piezoelectric fields in the light-emitting layer 210 and thus exhibits improved optical properties.

The activation layer 230, the first clad layer 220 and the second clad layer 240 constituting the light-emitting layer 210 are nitride semiconductors composed of a compound of Group III-V elements such as nitrogen (N), indium (In), gallium (Ga), aluminum (Al), phosphorus (P) or arsenic (As).

The activation layer 230 is a single-crystal semiconductor in which quantum wells are composed of a compound of Group III-V elements e.g. GaN or InₓGa₁₋ₓN.

In the ternary compound, InₓGa₁₋ₓN, constituting the activation layer 230, an indium (In) composition X is in the range of 0<X<1.

The first clad layer 220 and the second clad layer 240 arranged over and under the activation layer 230, respectively, are single-crystal semiconductors composed of a ternary compound (e.g. Al_{Y}Ga_{1-Y}N or In_{X}Ga_{1-X}N) of Group III-V elements.

The first and second clad layers 220 and 240 are ternary nitrides e.g. Al_{Y}Ga_{1-Y}N of Group III-V elements. When first and second clad layers 220 and 240 are composed of Al_{Y}Ga_{1-Y}N, an aluminum (Al) composition Y is controlled in the range of 0<Y<0.3 such that the first and second clad layers 220 and 240 have an energy band gap of about 4.0 eV.

When first and second clad layers 220 and 240 are composed of In_{X}Ga_{1-X}N, an indium (In) composition X is controlled in the range of 0<X≦0.3 such that the first and second clad layers 220 and 240 have an energy band gap of about 4.0 eV.

The first and the second clad layers 220 and 240 are semiconductor layers developed on a substrate with an orientation inclined toward the axis [11 2̅2] at an angle of 40 to 60 degrees (most preferably, 56 degrees) with respect to the axis [1001], instead of nonpolar substrates with the orientation direction [10 1̅0], suffering from several drawbacks due to incomplete heterocrystal development techniques.

According to the second embodiment, by employing aluminum (Al) and indium (In) compositions, eliminating internal fields of the activation layer 230 resulting from piezoelectric fields and spontaneous polarization, while rendering the first and second clad layers 220 and 240 to have an energy band gap of about 4.0 eV, it is possible to improve light generation efficiency of the activation layer 230.

The aluminum (Al) and indium (In) compositions of the first clad layer 220 may be symmetrical to those of the second clad layer 240 within the respective predetermined ranges.

Specifically, when aluminum (Al) of the first clad layer 220 has a first composition in the range of 0<Y≦0.3, aluminum (Al) of the second clad layer 240 has a second composition Y′ in the range of 0<Y′≦0.3, different from the first composition Y. For example, when the first composition Y is 0.1, the second composition Y′ is 0.3.

By symmetrically controlling aluminum (Al) compositions Y and Y′ of first and second clad layers 220 and 240 within the desired ranges, it is possible to offset the activation layer 230 and prevent spontaneous polarization.

Similarly, by symmetrically controlling indium (In) compositions X and X′ of first and second clad layers 220 and 240 within the desired ranges, it is possible to offset stresses applied to the activation layer 130 and prevent spontaneous polarization.

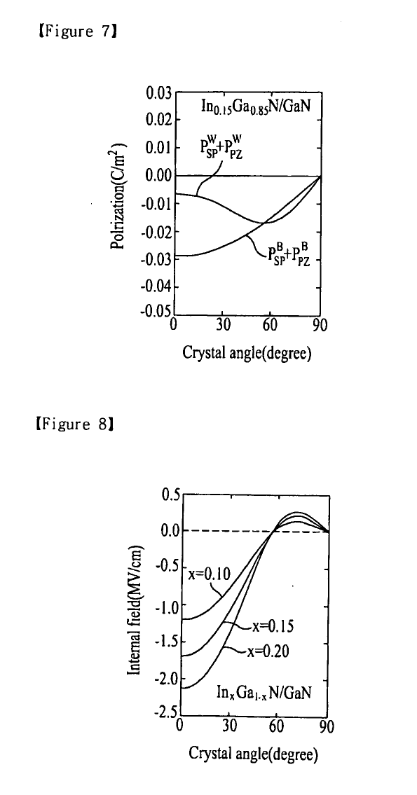

FIG. 7 is a graph showing piezoelectric fields and spontaneous polarization generated on the activation layer and clad layers of the semiconductor light-emitting diodes according to the first and second embodiments of the present invention.

Referring to FIG. 7, the semiconductor light-emitting diodes 100 and 200 of the first and second embodiments include the light emitting layer 110 and 210, respectively, each of which is a ternary or quaternary Group III-V nitride semiconductor composed of Al_{Y}Ga_{1-Y}N, In_{X}Ga_{1-X}N or In_{X}Al_{Y}Ga_{1-X-Y}N (clad layers), and GaN or In_{X}Ga_{1-X}N (activation layer). By controlling the compositions of indium (In), aluminum (Al) and gallium (Ga) constituting the first and second clad layers, it is possible to minimize piezoelectric fields and spontaneous polarization generated in the light emitting layer 110 and 210.

A more detailed description thereof will be given with reference to the case where the light emitting layer is a ternary or quaternary Group III-V nitride semiconductor composed of In_{X}Ga_{1-X}N (clad layers) and GaN (activation layer).

When the clad layers are composed of In_{X}Ga_{1-X}N, the indium (In) composition is controlled in order to minimize piezoelectric fields and spontaneous polarization.

In In_{X}Ga_{1-X}N constituting the clad layers, an indium (In) composition X is in the range of 0<X<1 and a gallium composition Y is thus in the range of 0<Y<1. Preferably, the indium (In) composition X is in the range of 0<X≦0.3 and the gallium composition Y is thus in the range of 0.7<Y≦1.

FIG. 7 is a graph showing polarization generated in the light emitting layer, in the case where the indium (In) composition X is 0.15 and the gallium composition V is 0.85. The theoretical values shown in FIG. 7 are calculated under the condition that thicknesses of the activation layer and the clad layer are 3 nm and 7 nm, respectively. The theoretical models are grounded on Alm et al., IEEE J Quantum Electron 41, 1253 (2005).

From FIG. 7, it can be confirmed that the control over the indium (In) composition of the quaternary nitride semiconductor enables control over spontaneous polarization generated on the light emitting layer.

Furthermore, it can be seen from FIG. 7 that when orientation of the substrate is changed toward the axis [11 2̅2] by a crystal angle (θ) of 40° to 70° with respect to the axis [0001], the semiconductor light-emitting diodes exhibit improved optical properties. In particular, when the crystal angle (θ) is 56°, spontaneous polarization of crystals is optimized.

The sum of piezoelectric fields and spontaneous polarization applied to the activation layer is calculated by the following Equation 6:

$${F}_{Z}^{W} \frac{[ ( {P}_{SP}^{b} + {P}_{PZ}^{b} ) - ( {P}_{SP}^{w} + {P}_{PZ}^{w} ) ]}{{ɛ}^{w} + \frac{{ɛ}^{b} {L}_{w}}{{L}_{b}}} \qquad Equation 6$$

wherein P is a type of polarization and L is a thickness of the activation layer or the clad layer.

Variations in internal field applied to the light-emitting layer, calculated by Equation 6, are shown in FIG. 8.

FIG. 8 is a graph showing internal fields applied to the light-emitting layers as a function of crystal angle (θ) with respect to semiconductor LEDs according to the first and second embodiments of the present invention.

It can be seen from FIG. 8 that when orientation of the substrate is changed toward the axis [11 2̅2] by a crystal angle (θ) of 40° to 70° (most preferably, 56°) with respect to the axis [0001], internal fields applied to the light-emitting layer 110 are decreased. In particular, when the crystal angle (θ) is 56°, internal fields of crystals are eliminated and most improved optical properties of LEDs are thus realized.

In addition, under the condition that the indium (In) composition X and gallium (Ga) composition V are (X=0.1, V=0.9), (X=0.15, V=0.85) and (X=0.20, V=0.80), [11 2̅2] crystals whose crystal angle (θ) is 56° have no internal field (zero).

That is to say, variation in orientation of the substrate by 40° to 70° causes a reduction in internal field generated in the light-emitting layer, and in particular, elimination of internal field at the optimum crystal angle of about 56° irrespective of the In composition.

The principle that internal fields in the light-emitting layer is reduced has been described with respect to the example where the light emitting layer is a ternary or quaternary Group III-V nitride semiconductor composed of In_{X}Ga_{1-X}N (clad layers) and GaN (activation layer). This example is given for the purpose of illustration and is not to be construed as limiting the scope of the invention. Accordingly, ternary or quaternary Group III-V nitride semiconductors employing clad layers composed of one selected from Al_{Y}Ga_{1-Y}N, In_{X}Ga_{1-X}N and In_{X}Al_{Y}Ga_{1-X-Y}N and an activation layer composed of GaN or In_{X}Ga_{1-X}N can realize the same effects as above via variation in orientation of the substrate by 40 to 70 degrees (optimum crystal angle: about 56°).

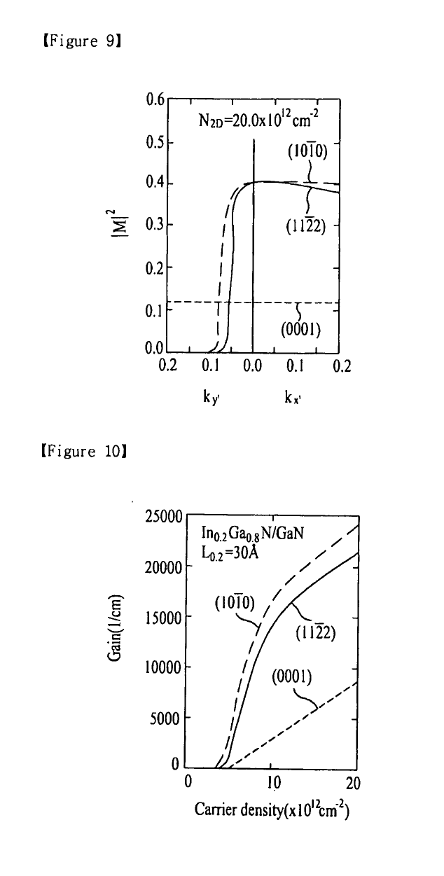

FIGS. 9 and 10 are graphs comparing optical properties of a LED employing a [10 1̅0]-oriented non-polar substrate and quaternary nitride semiconductor LEDs tilted 56° toward the axis [11 2̅2] according to the first and second embodiments of the present invention.

The semiconductor LEDs 100 and 200 include the light emitting layer 110 and 210, respectively, each of which is a ternary or quaternary Group III-V nitride semiconductor includes clad layers composed of Al_{Y}Ga_{1-Y}N, In_{X}Ga_{1-X}N or In_{X}Al_{Y}Ga_{1-X-Y}N and an activation layer composed of GaN or In_{X}Ga_{1-X}N. FIGS. 9 and 10 show optical property data of LEDs where the clad layers are composed of In_{X}Ga_{1-X}N and the activation layer is composed of GaN.

It can be confirmed from FIGS. 9 and 10 that LEDs according to the first and second embodiments, in which the clad layers are composed of In_{X}Ga_{1-X}N and the activation layer is composed of GaN, exhibit superior optical properties, as compared to a [0001]-oriented substrate-employing LED.

In addition, the optical properties of the LEDs according to the first and second embodiments are slightly-deteriorated, but substantially comparable to the LED employing a [10 1̅0]-oriented nonpolar substrate.

However, the [10 1̅0]-oriented non-polar substrate is disadvantageous in terms of fabrication efficiency due to instability in crystals developed thereon, while the substrates of the first and second embodiments whose orientation are changed by 40° to 70° (optimum crystal angle: 56°) toward the axis [11 2̅2] are advantageous in terms of fabrication efficiency due to stability in crystals developed thereon.

When semiconductor LEDs are fabricated on the substrate whose orientation is changed by 40° to 70° (optimum crystal angle: 56°) toward the axis [11 2̅2] using ternary Group III-V nitride with a desired composition, they can exhibit improved high fabrication efficiency and high optical efficiency, as compared to the case where a non-polar substrate suffering from incomplete crystal development is used.

Theoretical models for the crystalline states of the [10 1̅0]-oriented non-polar substrate and substrates whose orientation are changed by 40° to 70° (optimum crystal angle: 56°) toward the axis [11 2̅2] are grounded on K. Nishizuka et al., Appl. Phys. Lett 87, 231901 (2005).

Theoretical models with respect to optical gains are grounded on D. Ahn, Prog. Quantum Electron. 21, 249 (1997); and D. Ahn, IEEE J Quantum Electron. 34, 344 (1998).

In the fore-mentioned embodiments, the first clad layers 120 and 220, the second clad layers 140 and 240, the activation layer 130 and 230 are Group III-V compound semiconductors employing elements such as aluminum (Al), gallium (Ga), indium (In), phosphorus (P), arsenic (As) or nitrogen (N). Alternatively, these layers may employ semiconductors composed of Group II-VI compounds such as ZnO or CdMgZnO.

FIG. 11 is a sectional view illustrating the structure of a ternary oxide semiconductor light-emitting diode according to a third embodiment of the present invention.

As shown in FIG. 11, a ternary oxide semiconductor light-emitting diode 300 comprises a buffer layer 350 doped with conductive impurities and developed with an orientation inclined toward the axis [11 2̅2] at an angle of 40 to 60 degrees (most preferably, 56 degrees) with respect to the axis [1001], a light-emitting layer 310 arranged on the buffer layer 350, a first electrode 360 arranged under the buffer layer 350 and a second electrode 370 arranged on the light-emitting layer 310.

The light-emitting layer 310 includes a first clad layer 320 generating carriers for light-emission from an electric field applied through the buffer layer 350, a second clad layer 340 generating carriers for light-emission from an electric field applied from the second electrode 370, and an activation layer 330 interposed between the first clad layer 330 and the second clad layer 350 and emitting light.

The activation layer 330, the first clad layer 320 and the second clad layer 340 constituting the light-emitting layer 310 are oxide semiconductors composed of a compound of Group II-VI elements such as zinc (Zn), cadmium (Cd), selenium (Se), tellurium (Te) or oxygen (O).

The activation layer 330 is a single-crystal semiconductor having quantum wells composed of a compound (e.g. ZnO) of Group II-VI elements.

The first clad layer 320 and the second clad layer 340 arranged over and under the activation layer 330, respectively, are single-crystal semiconductors composed of a ternary compound (e.g. MgZnO) of Group II-VI elements.

Based on the structure of the light-emitting diode 300, the light-emitting layer 310 converts electric energy, which is derived from an electric field applied to the first electrode 360 and the second electrode 370 arranged in lower and upper parts of the light-emitting diode 300, respectively, to light energy, to emit light.

According to the semiconductor LED 300 of the third embodiment, in the ternary compound, Mg_{J}Zn_{1-J}O, constituting the first and second clad layers 320 and 340, the magnesium (Mg) and zinc (Zn) compositions are controlled so as to minimize piezoelectric fields and spontaneous polarization generated in the light emitting layer 110 and 210.

The magnesium (Mg) composition J is in the range of 0<J≦0.33 and the zinc (Zn) composition is thus in the range of 0.6<Zn≦1.

The first and the second clad layers 320 and 340 are semiconductor layers developed with an orientation inclined toward the axis [11 2̅2] at an angle of 40° to 70° with respect to the axis [0001] on a [0001]-oriented substrate, instead of nonpolar substrates with an orientation [10 1̅0], suffering from several drawbacks due to incomplete heterocrystal development techniques.

Under the foregoing orientation, the semiconductor LED 300 of the third embodiment is capable of reducing piezoelectric fields and spontaneous polarization of the light-emitting layer 310 and increasing light generation efficiency thereof via control over the (Mg) and zinc (Zn) compositions.

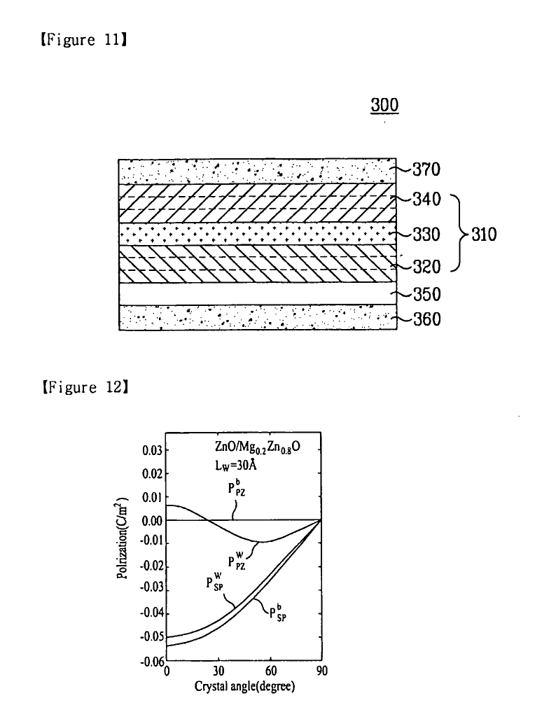

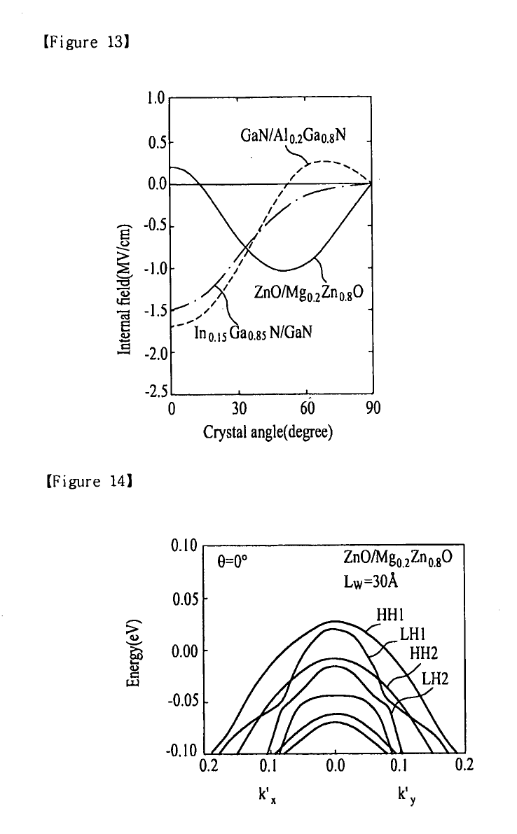

FIG. 12 is a graph showing piezoelectric field applied to the light-emitting layer 310 of the semiconductor light-emitting diode 300 according to the third embodiment of the present invention. FIG. 13 is a graph showing internal field applied to the light-emitting layer 310 of the semiconductor LED 300 according to the third embodiment of the present invention as a function of crystal angle (θ).

The data shown in FIGS. 12 and 13 are obtained from the light-emitting layer where the activation layer is composed of ZnO and the clad layers are composed of Mg_{0.2}Zn_{0.8}O.

From FIG. 12, it can be seen that when the activation layer composed of ZnO and the clad layers composed of Mg_{0.2}Zn_{0.8}O are developed on a substrate having an orientation changed by a crystal angle (θ) of 15° with respect to the orientation [0001], piezoelectric field, spontaneous polarization and internal field are eliminated (minimized), and on the other hand, when these layers are developed on a substrate having an orientation changed by a crystal angle (θ) of 50 to 60°, absolute values of piezoelectric field, spontaneous polarization and internal field are maximized.

From FIG. 13, it can be seen that the Group III-V semiconductor LEDs according to the first and second embodiments have minimum spontaneous polarization and internal field at the crystal angle (θ) of 56°.

Meanwhile, the Group II-VI semiconductor LED according to the third embodiment has minimum internal field at the crystal angle (θ) of 15° and absolute maximum internal field at the crystal angle (θ) of 50 to 60°.

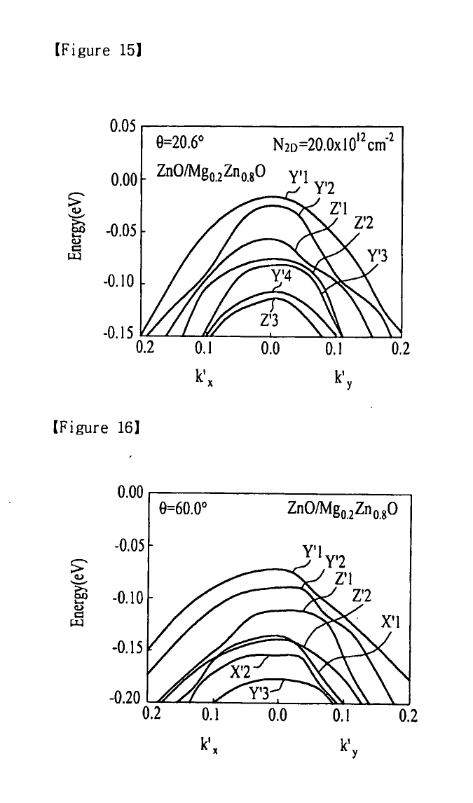

FIGS. 14 and 17 are graphs showing distribution of holes confined in an activation layer as a function of crystal angle (θ).

More specifically, FIG. 14 shows distribution of holes confined in an activation layer having quantum wells at θ=0°, FIG. 15 shows distribution of holes confined in an activation layer having quantum wells at θ=20.6°, FIG. 16 shows distribution of holes confined in an activation layer having quantum wells at θ=60°, and FIG. 17 shows distribution curves of holes confined in an activation layer having quantum wells at θ=90°.

The distribution model of such a hole distribution is grounded on S. H. Park and S. L. Chuang, Phys. Rev. B59, 4725 (1999).

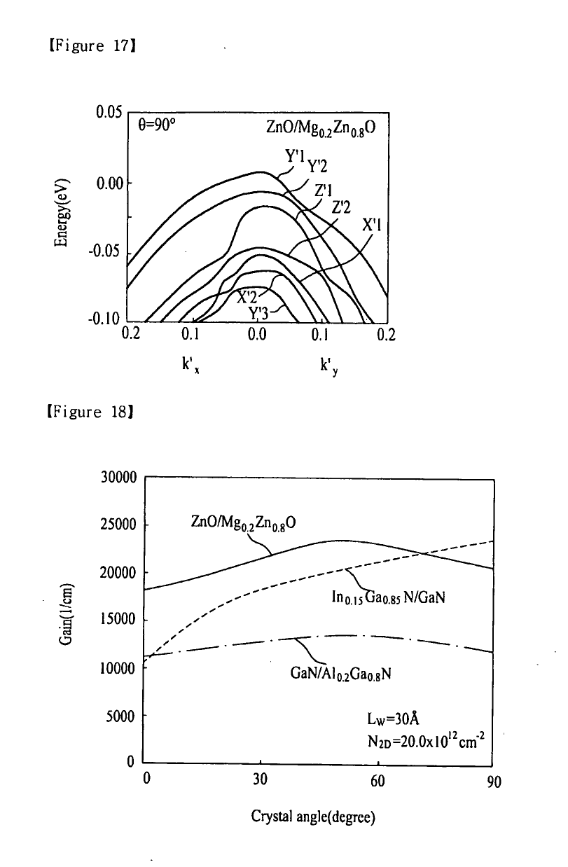

FIG. 18 is a graph showing optical gains as a function of crystal angle (θ) with respect to the semiconductor LED of the third embodiment where the activation layer is composed of ZnO and the clad layers are composed of Mg_{0.2}Zn_{0.8}O. As can be seen from FIG. 18, the optical gain is maximized at about θ=50°.

The theoretical model related to the optical gain is grounded on D. Ahn, Prog. Quantum Electron. 21, 249 (1997); D. Ahn, IEEE J Quantum Electron. 34, 344 (1998).

These results ascertain that when the semiconductor LED 300 according to the third embodiment is designed such that the activation layer 310 is composed of ZnO and the clad layers are composed of Mg_{0.2}Zn_{0.8}O and the orientation of the substrate is tilted toward the orientation [1122] by the crystal angle of 50° with respect to the orientation [0001], internal field is not zero, but optical gain is maximized.

This behavior is one of inherent characteristics of oxide semiconductors, which occurs because an optical gain obtained from the semiconductor structure by the elimination of internal field at θ=50° is greater than that of the case of θ=15°.

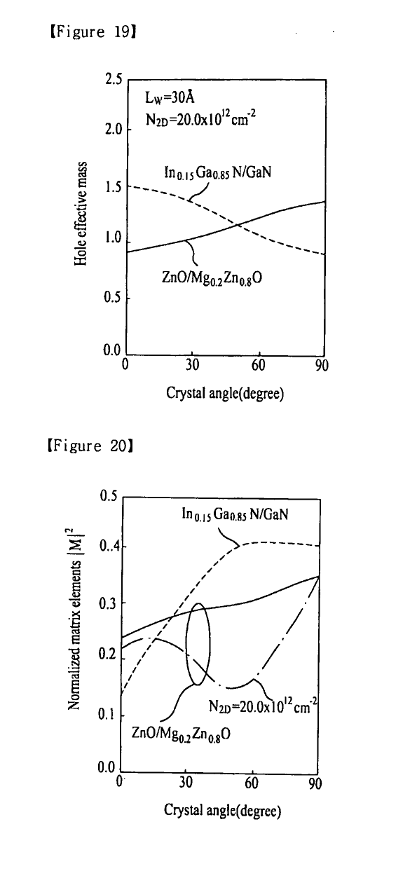

Referring to FIGS. 19 and 20, the principle that optical gain is maximized at a crystal angle of 50° will be illustrated.

Optical matrix elements determining a hole effective mass and optical gain depend upon the crystal angle.

The optical gain is in inverse proportion to the hole effective mass, but in proportion to the matrix elements. The two effects, electrical structure and internal field result in optimum optical properties of LEDs when the substrate orientation is inclined toward the axis [1122] by the crystal angle of 50° with respect to the axis [0001]. This behavior of optical properties is an inherent property of Group II-VI oxide semiconductor devices caused by the complicated electrical structure inside the light-emitting layer 310.

The semiconductor LED 300 according to the third embodiment is fabricated by developing ternary Group II-VI oxide on a substrate with an orientation inclined toward the axis [11 2̅2] at an angle of 30 to 70 degrees (most preferably, 50 degrees) with respect to an orientation [0001], instead of nonpolar substrates, suffering from several drawbacks due to incomplete heterocrystal development techniques.

Theoretical models for the crystalline states of the [10 1̅0]-oriented non-polar substrate and substrates whose orientation are tilted toward the axis [11 2̅2] by 50° are grounded on K. Nishizuka et al., Appl. Phys. Lett 87, 231901 (2005).

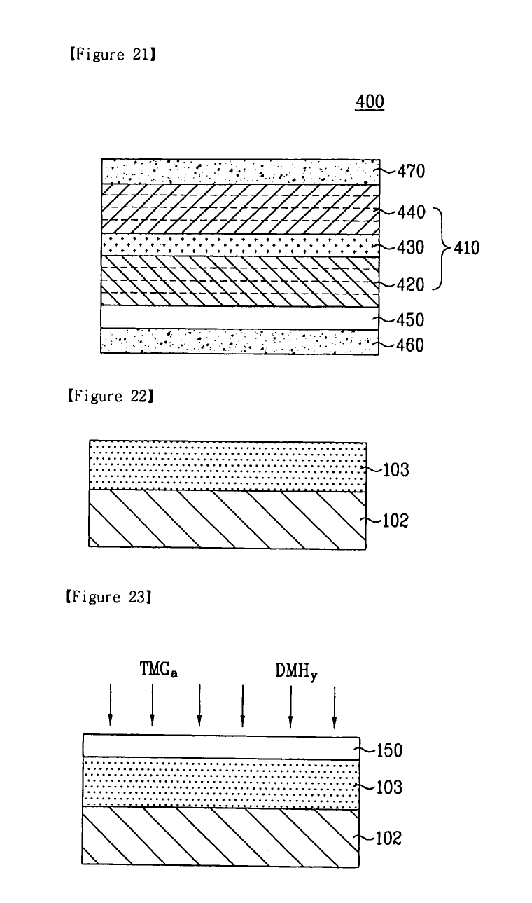

FIG. 21 is a sectional view illustrating the structure of a semiconductor light-emitting diode according to a fourth embodiment of the present invention.

The semiconductor light-emitting diode 400 of the second embodiment has the same structure and the effects, as those of the third embodiment, except for the light-emitting layers 310 and 410. Thus, a more detailed description thereof will be appreciated from the third embodiment.

The quaternary nitride semiconductor light-emitting diode 400 comprises a buffer layer 450 doped with conductive impurities and developed with an orientation inclined toward the axis [1122] by an angle of 40° to 70° with respect to the axis [0001], a light-emitting layer 410 arranged on the buffer layer 450, a first electrode 460 arranged under the buffer layer 450 and a second electrode 470 arranged on the light-emitting layer 410.

The light-emitting layer 410 includes a first clad layer 420 generating carriers for light-emission from an electric field applied through the buffer layer 450, a second clad layer 440 generating carriers for light-emission from an electric field applied from the second electrode 470, and an activation layer 430 interposed between the first clad layer 430 and the second clad layer 450 and emitting light.

The activation layer 430, the first clad layer 420 and the second clad layer 440 constituting the light-emitting layer 410 are oxide semiconductors composed of a compound of Group II-VI elements such as zinc (Zn), cadmium (Cd), selenium (Se), tellurium (Te) or oxygen (O).

The activation layer 430 is a single-crystal semiconductor in which quantum wells are composed of a compound (e.g. ZnO) of Group II-VI elements.

The first clad layer 420 and the second clad layer 440 arranged over and under the activation layer 430, respectively, are single-crystal semiconductors composed of a quaternary compound (e.g. CdMgZnO) of Group II-VI elements.

Based on the structure of the light-emitting diode 400, the light-emitting layer 410 converts electric energy, which is derived from an electric field applied to the first electrode 460 and the second electrode 470 arranged in lower and upper parts of the light-emitting diode 400, respectively, to light energy, to emit light.

In the quaternary compound, Cd_{K}Mg_{J}Zn_{1-k-J}O, constituting the first and second clad layers 420 and 440, the cadmium (Cd), magnesium (Mg) and zinc (Zn) compositions are controlled so as to improve optical efficiency of the light-emitting layer 410.

The cadmium (Cd) composition K and the magnesium (Mg) composition J are in the range of 0<K≦0.3 and 0<J≦0.33, respectively, and the zinc (Zn) composition is thus in the range of 0.37<Zn≦1.

The first and the second clad layers 420 and 440 are semiconductor layers developed on a substrate in a direction inclined toward the axis [11 2̅2] at an angle of 30 to 70 degrees (most preferably, about 50 degrees) with respect to the axis [1001], instead of nonpolar substrates with the orientation [10 1̅0], suffering from several drawbacks due to incomplete heterocrystal development techniques.

Under the foregoing orientation condition, the semiconductor LED 400 of the third embodiment is capable of reducing piezoelectric fields and spontaneous polarization of the light-emitting layer 410 and increasing light generation efficiency thereof via control over cadmium (Cd), magnesium (Mg) and zinc (Zn) compositions.

As shown in FIG. 18, when the semiconductor LED 400 according to the third embodiment is designed such that the activation layer 410 is composed of ZnO and the clad layers are composed of Cd_{K}Mg_{J}Zn_{1-k-J}O and the orientation of the substrate is changed toward the axis [1122] by the crystal angle of 50° with respect to the orientation [0001], internal field is not zero, but optical gain is maximized.

This behavior is one of inherent characteristics of oxide semiconductors, which occurs because an optical gain obtained from the semiconductor structure by the elimination of internal field at θ=50° is greater than that of the case of θ=15°.

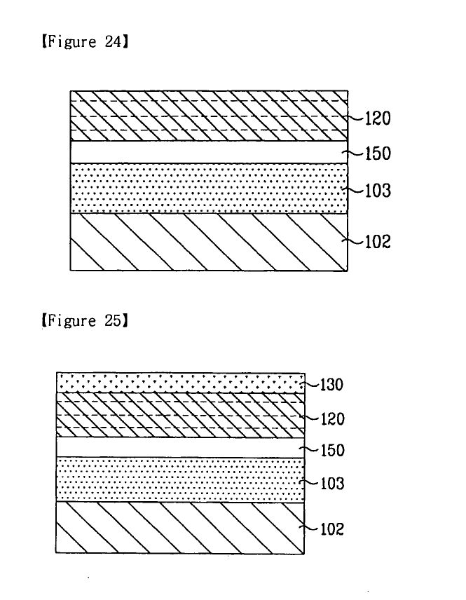

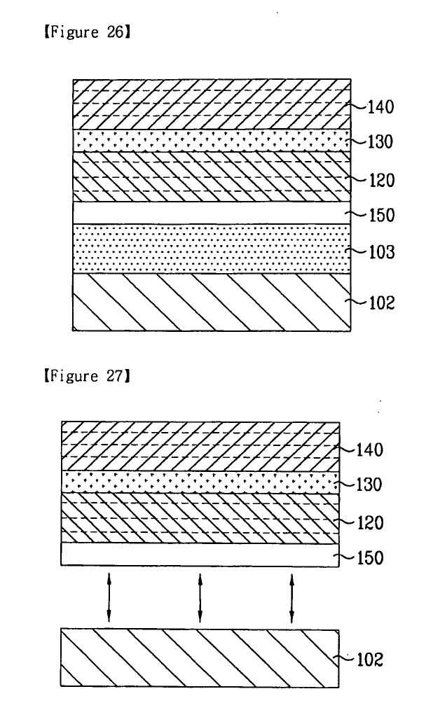

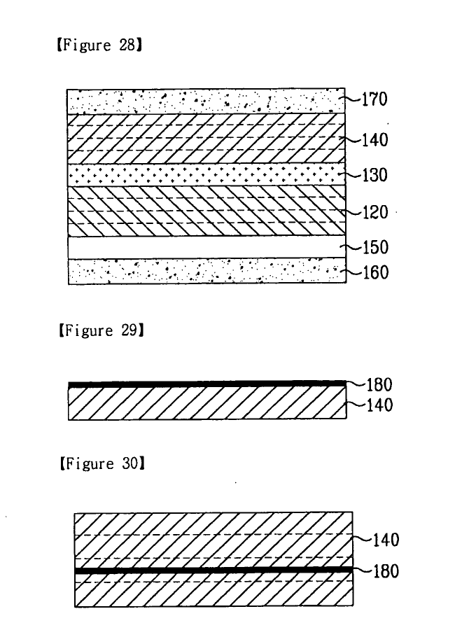

FIGS. 22 and 28 are sectional views illustrating a method for fabricating the semiconductor light-emitting diodes according to the embodiments of the present invention.

Referring to FIGS. 22 and 28, the method for fabricating the light-emitting diode according to an embodiment of the present invention will be illustrated below.

Sapphire, SiC, Si, ZrB, CrB, and the like may be used as a substrate 102, on which a nitride or oxide semiconductor is developed. When a compound semiconductor is directly developed on the substrate 102, satisfactory crystals cannot be developed thereon due to lattice mismatch. In this case, a buffer layer (e.g. GaN, AlN or SiC) is developed on the substrate and a compound semiconductor is then developed on the resulting structure, thereby developing high-quality crystals.

As shown in FIG. 23, a sacrificial layer 103 in the form of a single-crystal is formed on the substrate 102 using GaN (Group III-V nitride semiconductors) or ZnO (Group II-VI oxide semiconductors) such that the orientation of the sacrificial layer 103 is inclined toward the axis [11 2̅2] (i.e., the C-axis) by a crystal angle of 40° to 70° with respect to the axis [0001].

When the light-emitting layer is a Group III-V nitride semiconductor light-emitting diode according to the first and second embodiments, the optimum crystal angle θ is 56°. When the light-emitting layer is a Group II-VI oxide semiconductor light-emitting diode according to the third and fourth embodiments, the optimum crystal angle θ is 50°. Furthermore, according to the third and fourth embodiments, internal field of Group II-VI oxide semiconductor LEDs is zero at the crystal angle θ of 15°.

The sacrificial layer 103 is formed according to the following two methods.

First, GaN or ZnO is developed on the semiconductor substrate 102 such that GaN or ZnO has facets with a plurality of initial orientations. Of these, facets with the orientation [11 2̅2] are selectively developed and are then tilted by angles of 15°, 50° and 56° with respect to the facet of the substrate to form the sacrificial layer 103.

Second, the sacrificial layer 103 with the orientation [0001] is developed on the semiconductor substrate 102 with the orientation [0001]. The sacrificial layer 103 is etched along the direction [11 2̅2], or redeveloped while lying toward the direction [11 2̅2] to form the sacrificial layer 103 changed by angles of 15°, 50° and 56° with respect to the orientation [0001].

Then, as shown in FIG. 24, a buffer layer 150 is formed on the sacrificial layer 103 using dimethylhydrazine (DMHy; N₂H₂(CH₃)₂) as a nitrogen (N) source. The buffer layer 150 is doped with conductive impurities in order to form a light-emitting diode having a perpendicular structure.

The buffer layer 150 is composed of any one of GaN, AlN, ZnO and SiC, where the aluminum (Al) composition X, the gallium (Ga) composition Y and the zinc (Zn) composition Z are in the range of 0<X<1, 0<Y<1 and 0<Z<1, respectively.

Sources used to form the nitride or oxide buffer layer 150 are trimethylaluminum (TMAl), trimethylgallium (TMGa) and trimethylindium (TMIn).

Then, as shown in FIG. 24, a quaternary Group III-V nitride semiconductor of AlₓIn_{y}Ga_{1-x-y}N, a ternary Group III-V nitride semiconductor of Al_{X}Ga_{1-X}N, In_{Y}Ga_{1-Y}N, a quaternary Group II-VI oxide semiconductor of Cd_{I}Mg_{J}Zn_{1-I-J}O, or a ternary Group II-VI oxide semiconductor of Mg_{J}Zn_{1-J}O is developed in the form of single crystals on the buffer layer 150 to form a first clad layer 120.

When the first clad layer 120 is composed of a compound of Al_{X}In_{Y}Ga_{1-X-Y}N, the aluminum (Al) composition X, the indium (In) composition Y and the gallium (Ga) composition Z are combined in a predetermined ratio. AT this time, the aluminum (Al) composition X, the indium (In) composition Y and the gallium (Ga) composition Z are in the range of 0<X≦0.3, 0<Y≦0.3 and 0.4<Z≦1, respectively.

When the first clad layer 120 is composed of a ternary compound of Al_{X}Ga_{1-X}N or In_{Y}Ga_{1-Y}N, the aluminum (Al) composition X, the indium (In) composition Y and the gallium (Ga) composition Z are in the range of 0<X≦0.3, 0<Y≦0.3 and 0.4<Z≦1, respectively.

When the first clad layer 120 is composed of a quaternary Group II-VI oxide semiconductor of Cd_{I}Mg_{J}Zn_{1-I-J}O, a cadmium (Cd) composition I, a magnesium (Mg) composition J and a zinc (Zn) composition are controlled in an appropriate ratio. At this time, the cadmium (Cd) composition I and the magnesium (Mg) composition J are in the range of 0<I≦0.3, 0<J≦0.33, respectively, and the zinc (Zn) composition is thus in the range of 0.37≦Z<1.

When the first clad layer 120 is composed of a ternary compound of Mg_{J}Zn_{1-J}O, the magnesium (Mg) composition J and the zinc (Zn) composition are in the range of 0<J≦0.33 and 0.67≦Zn<1.

Then, as shown in FIG. 25, a Group III-V nitride semiconductor composed of GaN or Group II-VI oxide semiconductor composed of ZnO is developed in the form of single crystals on the first clad layer 220 to form an activation layer 130.

Then, as shown in FIG. 26, a second clad layer 140 is formed on the activation layer 130. The structure and formation method of the second clad layer 140 is the same as those of the first layer 130 as shown in FIG. 24, except that a delta-doped layer is formed inside the second clad layer 140.

The common elements constituting the first clad layer 120 and the second clad layer 140 differ in composition within the acceptable ranges.

A p-type delta-doped layer 180 may be formed on the second clad layer 140 as shown in FIG. 4. The formation of the p-type delta-doped layer 180 may be carried out, as shown in FIGS. 29 and 30.

The p-type delta-doped layer 180 is formed in the process of forming the second clad layer 140. As shown in FIG. 29, the p-type delta-doped layer 180 is formed by forming one or two films using a quaternary or ternary compound constituting the second clad layer 140 and sputtering, depositing or implanting a p-type material such as magnesium (Mg) on the films.

The closer the p-type delta-doped layer 180 and the activation layer 130 are to each other, the higher the optical efficiency of semiconductor LEDs.

The compositions of the elements constituting the first clad layer 120 and the second clad layer 240 may be symmetrical to each other within the respective predetermined ranges.

More specifically, in a case where the aluminum (Al) composition of the first clad layer 120 and the second clad layer 140 is within a specific range, when aluminum (Al) of the first clad layer 120 has a first composition, aluminum (Al) of the second clad layer 240 has a second composition different from the first composition.

By symmetrically controlling the aluminum (Al) composition of the first clad layer 120 and the second clad layer 140 within the desired ranges, it is possible to offset the stress applied to the activation layer 130 and prevent spontaneous polarization.

The aluminum (Al) is exemplified as an element for the clad layers. Examples of elements for the clad layers whose composition is symmetrically controllable include, but are not limited to aluminum (Al), indium (In), gallium (Ga), zinc (Zn), cadmium (Cd) and magnesium (Mg).

In ZnO/CdMgZnO Group II-VI compound semiconductors, symmetrically controlling cadmium (Cd), magnesium (Mg) and zinc (Zn) compositions constituting the first and second clad layers 120 and 140, it is possible to offset stresses applied to the activation layer and prevent spontaneous polarization.

Then, as shown in 27, the sacrificial layer 103 interposed between the substrate 102 and buffer layer 150 is chemically removed to separate the substrate 102 from the compound semiconductors 120, 130, 140 and 150.

The separation of the substrate 102 from the remaining structure may be carried out after forming the first clad layer 120 on the buffer layer 150.

In this case, after the buffer layer 150 and the first clad layer 120 are sequentially formed, the activation layer 130 and the second clad layer 140 are formed sequentially on the first clad layer 120.

Then, as shown in FIG. 28, a first electrode 160 is formed under the buffer layer 150 using a conductive material and a second electrode 170 is formed over the second clad layer 140 using a conductive material to complete fabrication of the semiconductor light-emitting diode.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

### INDUSTRIAL APPLICABILITY

As apparent from foregoing, the semiconductor light-emitting diode according to an embodiment of the present invention, a light-emitting layer is formed on a substrate with an orientation inclined toward the axis [1122] at an angle of 40° to 70° with respect to the axis [0001], and compositions of Group III-V and Group II-VI compounds constituting first and second clad layers are controlled. As s result, it is possible to offset the stresses applied to an activation layer and prevent spontaneous polarization. As a result, the light-emitting diode can exhibit improved light efficiency.

1-49. (canceled)

50. A semiconductor light emitting device, comprising:
a [0001]-oriented substrate;
a buffer layer developed with an orientation inclined toward an [1122] plane at a predetermined angle with respect to a [0001] plane on the [0001]-oriented substrate;
a light-emitting layer arranged over the buffer layer, the light-emitting layer including a first clad layer, a second clad layer and an activation layer interposed between the first clad layer and the second clad layer;
a first electrode electrically contacted with the first clad layer; and
a second electrode electrically contacted with the second clad layer.

51. The semiconductor light emitting device according to claim 50, wherein the light-emitting layer is composed of Group III-V nitride semiconductor.

52. The semiconductor light emitting device according to claim 51, wherein the predetermined angle is in a range of about 40° to 70°.

53. The semiconductor light emitting device according to claim 52, wherein the buffer layer is composed of any one of GaN, MN, ZnO, MgZnO and SiC.

54. The semiconductor light emitting device according to claim 52, wherein the activation layer is composed of any one of GaN and In_{X}Ga_{1-X}N (0<X<1).

55. The semiconductor light emitting device according to claim 52, wherein the first and second clad layers are composed of any one of In_{X}Ga_{1-X}N (0<X<0.3), Al_{Y}Ga_{1-Y}N (0<Y<0.3) and In_{X}Al_{Y}Ga_{1-X-Y}N (0<X<0.3, 0<Y<0.3).

56. The semiconductor light emitting device according to claim 52, wherein at least one of the first and second clad layers includes a p-type delta-doped layer.

57. The semiconductor light emitting device according to claim 50, wherein the light-emitting layer is composed of Group II-VI oxide semiconductor.

58. The semiconductor light emitting device according to claim 57, wherein the predetermined angle is in a range of about 15° or 40° to 70°.

59. The semiconductor light emitting device according to claim 58, wherein the buffer layer is composed of any one of GaN, AlN, ZnO, MgZnO and SiC.

60. The semiconductor light emitting device according to claim 58, wherein the activation layer is composed of any one of ZnO and Mg_{X}Zn_{1-X}O (0<X<1).

61. The semiconductor light emitting device according to claim 58, wherein each of the first and second clad layers is composed of any one of Mg_{X}Zn_{1-X}O (0<X<0.33) and Cd_{Y}Mg_{X}Zn_{1-X-Y}O (0<X<0.33, 0<Y<0.3).

62. The semiconductor light emitting device according to claim 58, wherein at least one of the first and second clad layers includes a p-type delta-doped layer.

63. A method for fabricating a semiconductor light emitting device having a [0001]-oriented substrate; a buffer layer; a light-emitting layer arranged over the buffer layer, the light-emitting layer including a first clad layer, a second clad layer and an activation layer interposed between the first clad layer and the second clad layer; a first electrode electrically contacted with the first clad layer; and a second electrode electrically contacted with the second clad layer, the method comprising the steps of:
forming the buffer layer having an orientation inclined toward a [1122] plane at an angle of 15°, or 40° to 70° with respect to a [0001] plane on the [0001]-oriented substrate;
forming the light-emitting layer on the buffer layer; and
forming the first electrode and the second electrode.

64. The method for fabricating the semiconductor light emitting device according to claim 63, wherein the step of forming the buffer layer comprises the steps of:
developing the [0001]-oriented buffer layer on the [0001]-oriented substrate;
etching or laying the buffer layer along the orientation [1122] to obtain crystal facets with the orientation [1122]; and
developing the [1122]-oriented crystal facets to form the buffer layer.

65. The method for fabricating the semiconductor light emitting device according to claim 63, wherein the step of forming the buffer layer comprises the steps of:
developing GaN or ZnO in the form of crystals with a plurality of initial orientations; and,
selectively developing the crystals with facets inclined toward the orientation [1122] at an angle of 15°, or 40° to 70° with respect to the [0001] plane.

66. The method for fabricating the semiconductor light emitting device according to claim 63, further comprising the steps of:
removing the [0001]-oriented substrate after forming the light-emitting layer on the buffer layer;
forming a first electrode under the buffer layer; and
forming a second electrode on the second clad layer.

67. The method for fabricating the semiconductor light emitting device according to claim 66, wherein the buffer layer is formed by being doped with conductive impurities.
